(19) United States
(12) Patent Application Publication
(10) Pub. No.: US 2007/0054115 A1
(43) Pub. Date: Mar. 8, 2007

(54) METHOD FOR CLEANING PARTICULATE FOREIGN MATTER FROM THE SURFACES OF SEMICONDUCTOR WAFERS

(75) Inventors: Steven R. Codding, Underhill, VT (US); Petra U. Klinger-Park, Jericho, VT (US); Timothy C. Krywanczyk, Essex Junction, VT (US)

Correspondence Address: SCULLY, SCOTT, MURPHY & PRESSNER, 400 GARDEN CITY PLAZA, GARDEN CITY, NY, 11530, US

(73) Assignee: INTERNATIONAL BUSINESS MACHINES CORPORATION, Armonk, NY (US)

(21) Appl. No.: 11/162,369

(22) Filed: Sep. 8, 2005

(51) Int. Cl. B32B 37/12; B32B 38/10; B32B 38/16; H01L 21/30; B32B 7/12

(52) U.S. Cl. 428/343; 156/247; 156/281; 156/154; 156/152; 438/459

(57) ABSTRACT

System and method for applying an adhesive tape or a pressure release tape to a surface of the semiconductor wafer to remove particulate contaminants or foreign material that may have been collected thereon. The pressure-release tape to which the foreign material is adherent is peeled off or removed from the surface of the semiconductor wafer. Advantageously, a pressure-sensitive adhesive tape may be utilized which does not require any intermediate steps between application thereof onto the surface substrate. The adhesive tape provides a novel degree of adhesion to a surface of the substrate compared to the tapes employed in the art, in order to increase the efficiency in removing the foreign materials. Moreover, no residue is left from the pressure-sensitive tape on the surface of the substrate or semiconductor wafer after the step of removing the tape to which the foreign material has adhered.

### DESCRIPTION

### FIELD OF THE INVENTION

The present invention relates to a method for cleaning the surfaces of semiconductor wafers from the presence of foreign matter, such as particulate impurities and contaminants. Moreover, more particularly, the present invention is directed to a method of cleaning the surfaces of semiconductor wafers from particulate foreign matter (FM) deposited thereon by debris from broken wafers produced during manufacture, during transport or any other kind of deposits. The present invention also pertains an arrangement for cleaning the surfaces of semiconductor wafers from particulate foreign matter and other kinds of contaminants deposited thereon, such as may be caused by particles of broken semiconductor wafers produced during manufacture or during transport of the wafers while being processed. In particularly, the problems of semiconductor wafer breakage may be encountered when transported in a FOUP device, or during a process step, while and other methods of processing and handling the semiconductor wafers may also create foreign material deposited on the surface of the wafers.

### BACKGROUND OF THE INVENTION

When implementing the manufacture of semiconductor wafers, particularly in connection with the presently high speed processes upon occasion, the manufacturing apparatus employed may cause the breakage of some of the semiconductor wafers and produce fragments and other foreign particulate matter (FM) and contaminants which are deposited on the surface of other semiconductor wafers, the latter of which are normally in an acceptable or satisfactory state of manufacture. These foreign matter deposits can also be caused during transport of the semiconductor wafers through the manufacturing facility or to other locations. In order to clean the surfaces of the undamaged semiconductor wafers from the depositions of such foreign materials, for example, particulate fragments from the broken or damaged semiconductor wafers, various cleaning methods have been developed in current the technology, including chemical cleaning of the surfaces of the semiconductor wafers, dry cleaning and also the utilization of various types of adhesive tapes, which may cause an adherence of residues of the foreign material to adhere to the semiconductor wafer thereto, as these tapes are removed from the surfaces of the semiconductor wafers onto which they were previously adhesively attached.

Although various of these presently known methods and arrangements for maintaining the cleanliness of semiconductor wafer surfaces are generally satisfactory, they are normally complex in nature and may at times even be deleterious to the integrity and quality of the semiconductor wafers and any components located therein being produced in the manufacturing facility.

In essence, pursuant to the current state of the technology, the removal of foreign matter from the surfaces of the a substrate, such as a semiconductor wafer, necessitates generally intermediate steps having to be taken between the application and removal of the tape onto the surface of the semiconductor wafer or substrate, which may alter the material state of the tape. For example, ultraviolet radiation or thermal processes may be necessary in order to essentially “cure” the tape, as may be required in the prior art, in order to effect release thereof from adherence to the semiconductor surface.

Although, typically, semiconductor wafers may be cleaned by means of chemical wet cleaning steps, such as diverse types of surface-cleaning solvents and chemicals, a problem may be encountered in that wet cleaning may present a possible incompatibility with the integrity of the surfaces of the semiconductor wafers, wherein, for instance, is C4 and DI water or aluminum lines and NH₄OH may be incompatible with the wafer material and cause some damage to the surfaces.

Currently, pursuant to Chen, et al., U.S. Pat. No. 6,320,269 B1, a tape may be applied to the surface of a wafer in order to protect the latter during a grinding operation. The surface is formed by the upper surface of a passivation layer and bonding pads, which are exposed through holes formed in a passivation layer, whereas the tape is provided with a plastic backing and an adhesive.

Kataoka, et al., U.S. Pat. No. 6,159,827 is directed to a process for preparing semiconductor wafers, wherein an adhesive tape is applied on the front surface of the wafer, the back surface of the wafer is ground, the adhesive tape is peeled away from the surface and the front surface of the semiconductor wafer is cleaned. The adhesive tape has heat shrinkability and after grinding the back surface of the semiconductor wafer, warm water at a temperature from 50° to 99° C. is poured onto the surface to be able to peel the adhesive tape from the wafer in a wafer cleaning machine. Thereafter, the front surface of the semiconductor wafer is cleaned in the machine.

Konda, et al, U.S. Pat. No. 5,902,678 discloses the use of a pressure sensitive adhesive or tape for removing foreign matter that is present on the surface of an article. The pressure sensitive adhesive tape has a property of curing with an actinic energy source in order to provide a three-dimensional network molecular structure and a modulus of elasticity for curing of lower than 1 kg/mm² and a modulus of elasticity after curing of 1 kg/mm² or higher, with a degree of volumetric shrinkage of 2% or higher caused by the curing.

Other publications, such as Japanese Publication Nos. JP 10-098090; JP 09-266188; and JP 08-107098, describe various aspects of employing adhesive tapes to a surface of a substrate which is to be cleaned. All of these require various curing and preparation of the tape surfaces through either ultraviolet radiation or other water or chemicals.

### SUMMARY OF THE INVENTION

Accordingly, in order to avoid the complexities and difficulties encountered in connection with the prior art, the present invention utilizes a pressure-sensitive adhesive tape which does not require any intermediate steps between the protective application thereof onto a front surface of a substrate, such as a semiconductor wafer on which foreign material has been collected, possibly through the breakage of other semiconductor wafers which are being processed or the like, or during grinding of the backside of the wafer for thinning the latter, wherein the pressure-sensitive adhesive tape provides a novel degree of adhesion to a surface of the substrate compared to the tapes employed in the art, in order to increase the efficiency in removing the foreign materials. Moreover, no residue is left from the pressure-sensitive tape on the surface of the substrate or semiconductor wafer after the step of removing the tape to which the foreign material (FM) has adhered.

Accordingly, pursuant to the present invention, there is applied an adhesive tape or a pressure release tape to the front surface of the semiconductor wafer, which is to be protected during grinding of the backside of the wafer, whereby particulate contaminants or foreign material (FM) thereon, which may be have collected on the front side of the wafer, adhere to the surface of the tape. Thereafter, the pressure-release tape to which the foreign material (FM) is adherent is peeled off or removed from the front surface of the semiconductor wafer, which it has protected, and the latter has N₂ blown there across in order to blow off any residual particles or contaminants.

The foregoing tape application and peeling off steps may then be repeated as necessary, possibly 1-3 times in order to remove any further contaminants or foreign material which may be revealed during inspection of the front surface of the semiconductor wafer.

Accordingly, it is an object of the present invention to provide a novel method of removing foreign materials from the surfaces of semiconductor wafers collected during manufacturing or transport thereof.

Another object of the present invention is to provide a novel method of applying a protective pressure sensitive tape to the front surface of semiconductor wafers during the grinding of the backsides of the wafers to enable foreign material collected thereon be removed concurrently with the peeling of the tape from the surfaces of the semiconductor wafers.

Another object of the present invention resides in the provision of an arrangement for implementing the semiconductor wafer surface cleaning method pursuant to the invention.

### BRIEF DESCRIPTION OF THE DRAWINGS

Reference may now be made to the following detailed description of an embodiment of the invention, taken in conjunction with the accompanying drawings; in which:

FIG. 1 illustrates, generally diagrammatically, a semiconductor wafer having foreign materials deposited on a front surface thereof; and

FIG. 2 illustrates the application of a pressure sensitive adhesive tape on the front surface of the semiconductor wafer in order to remove the foreign material in a surface cleaning operation responsive to peeling the tape from the wafer surface.

### DESCRIPTION OF PREFERRED EMBODIMENTS OF THE INVENTION

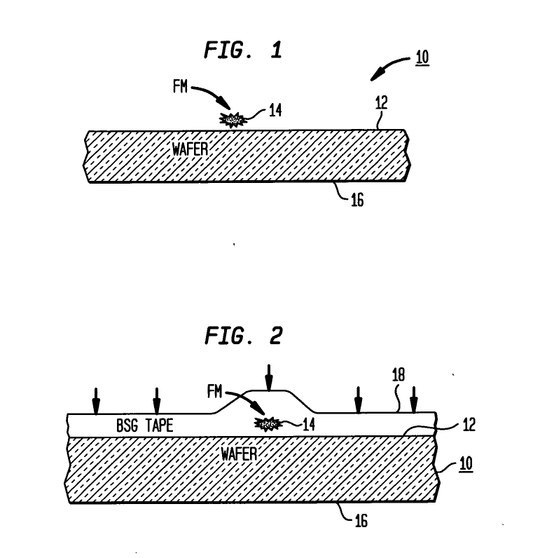

Referring now in detail to the drawings, FIG. 1 illustrates, generally diagrammatically, a side view of a semiconductor wafer 10, which is in the process of being manufactured. The upper or front surface 12 of the semiconductor wafer 10, which has electronic components, C4s or pads thereon, may have foreign material (FM) or particulate debris 14 deposited thereon, possibly during a previous breakage of other semiconductor wafers encountered while being transported in a FOUP/FOSB device, or during a manufacturing process step. These foreign materials 14 could also conceivably be created by other handling steps during manufacture or transport and require to be cleaned from the wafer surface in order to be able to further process the wafer in the manufacture of such semiconductor devices. Moreover, such foreign material 13 is produced during grinding of the back surface 16 of the semiconductor wafer 10, and necessitates protecting the front surface 12 and any components arranged thereon.

In order to be able to easily remove the foreign material 14 from the front surface 12 of the wafer 10, as illustrated in FIG. 2 of the drawings, a pressure-sensitive adhesive release tape 18, for example, such as a backside grind or thinning tape (BSG), dicing tape (DSP) or any other similar kind of pressure-sensitive release tape is applied to the front surface 12 of the wafer protectively covering the latter, including adhesively contacting any foreign materials 14 or particulate debris deposited thereon.

This tape 18 can be applied by means of surface pressure, or through the application of a vacuum between wafer 10 and the tape. A vacuum arrangement for that purpose is disclosed in Attorney Docket No. END920050062US1 (18910); the disclosure of which is incorporated herein by reference.

Concerning the foregoing, unlike the prior art, the pressure-sensitive tape 18 does not require any previous curing or treatment, such as through UV radiation to reduce its tacking and enables a simple method of cleaning the surface of the semiconductor surface on which it has been applied. Thus, it is merely necessary to peel off or remove the tape 18 from the front wafer surface 12, whereby any foreign materials 14 present on the surface will adhere to the tape 18 and will be pulled off along with the removal of the tape.

Additionally, subsequent to the removal of the tape 18 and the thereto adherent foreign material 14, any remaining particles on the surface of the semiconductor wafer or substrate may be removed by being blown off through the use of N₂ in a generally gaseous state, or by a repetition of the foregoing process, if warranted in response to an inspection of the wafer surface 12 for cleanliness.

A typical pressure-sensitive release tape 18 may have an adhesive thickness which can vary of between 5 μm and 100 μm with a tack level of 5 grams to 100 grams in a Nitto pressure tape.

To the contrary, a typical UV-tape tack level may be 300 grams prior to curing and drop to less than 15 grams post UV tape radiation treatment. This clearly evidences that the present tape, without necessitating altering through UV radiation or “curing”, has a stronger adhesion to the surface 12 of the wafer 10, and resultingly a higher material-removing efficiency, while avoiding any residues remaining on the wafer front surface 12.

However, these properties are only set forth by way of example, and other pressure-sensitive release tapes can be employed for removing the impurities and the foreign material from the surfaces of the semiconductor wafers. In order to ensure the cleanliness of the semiconductor wafer surface, inspection thereof may require that the foregoing steps be repeated as many times as needed.

Furthermore, since such BSG tapes have been qualified in the semiconductor technology for use on semiconductor wafer surfaces, there is no compatibility issue present with regard to the use of tapes in the manufacture of such semiconductor wafers.

While the present invention has been particularly shown and described with respect to preferred embodiments thereof, it will be understood by those skilled in the art that the foregoing and other changes in forms and details may be made without departing from the scope and spirit of the present invention. It is therefore intended that the present invention not be limited to the exact forms and details described and illustrated, but fall within the scope of the appended claims.

What is claimed is:

1. A method of protecting a surface and removing contaminating foreign material from said surface of a semiconductor wafer, comprising the steps of:
applying a pressure-sensitive release tape to said protected surface; and
peeling said tape from said protected surface, whereby said contaminating foreign material is adherent to said tape and is removed from said semiconductor wafer surface in conjunction with said tape.

2. A method, as claimed in claim 1, wherein said protective tape is applied to the front surface of said semiconductor wafer so as to protect components arranged on said front surface during processing of a backside of said semiconductor wafer potentially generating foreign material and debris.

3. A method, as claimed in claim 1, wherein said processing of the backside comprises grinding said back surface of the semiconductor wafer for the thinning of said wafer.

4. A method, as claimed in claim 1, wherein said foreign material is produced by debris formed through the breakage of further semiconductor wafers tending to be deposited on the front surface of said first-mentioned semiconductor wafer.

5. A method, as claimed in claim 1, wherein said foreign material is produced by debris falling during transport of said semiconductor wafer.

6. A method, as claimed in claim 1, wherein said tape comprises a backside grinding and wafer thinning tape (BSG) or dicing tape (DSP) applied to the front surface of said wafer during grinding of the back surface of said wafer.

7. A method, as claimed in claim 1, wherein tape is applied a plurality of times to said wafer front surface for a complete removal, as required, of said foreign material.

8. A method as claimed in claim 1, wherein said front surface is subjected to a cleaning with N₂ gas after peeling off of said tape from said surface.

9. A method, as claimed in claim 1, wherein said tape has an adhesive thickness about between 5 μm and 100 μm with a tack level of about between 5 grams to 100 grams.

10. A method, as claimed in claim 1, wherein said steps of applying and peeling said tape are performed without an intermediate step of curing said tape.

11. An arrangement for protecting a surface and removing contaminating foreign material from said surface of a semiconductor wafer, comprising:
a pressure-sensitive release tape, which is applied to said protected surface; and
said tape being peeled from said protected surface, whereby said contaminating foreign material is adherent to said tape and is removed from said semiconductor wafer surface in conjunction with said tape.

12. An arrangement, as claimed in claim 11, wherein said protective tape is applied to the front surface of said semiconductor wafer so as to protect components arranged on said front surface during processing of a backside of said semiconductor wafer potentially generating foreign material and debris.

13. An arrangement, as claimed in claim 12, wherein said processing of the backside comprises grinding said back surface of the semiconductor wafer for the thinning of said wafer.

14. An arrangement, as claimed in claim 11, wherein said foreign material is produced by debris formed through the breakage of further semiconductor wafers tending to be deposited on the front surface of said first-mentioned semiconductor wafer.

15. An arrangement, as claimed in claim 11, wherein said foreign material is produced by debris falling during transport of said semiconductor wafers.

16. An arrangement, as claimed in claim 11, wherein said tape comprises a backside grinding and wafer thinning tape (BSG) or dicing tape (DSP) applied to the front surface of said wafer during grinding of the back surface of said wafer.

17. An arrangement, as claimed in claim 11, wherein said tape is applied a plurality of times to said wafer front surface for a complete removal, as required, of said foreign material and debris.

18. An arrangement, as claimed in claim 11, wherein said front surface is subjected to a cleaning with N₂ gas after peeling off of said tape from said surface.

19. An arrangement, as claimed in claim 11, wherein said tape has an adhesive thickness about between 5 μm and 100 μm with a tack level of about between 5 grams to 100 grams.

20. An arrangement, as claimed in claim 11, wherein said tape is cure-free.
